(19) United States
(12) Patent Application Publication
(10) Pub. No.: US 2024/0282796 A1
(43) Pub. Date: Aug. 22, 2024

(54) IMAGE SENSOR AND METHOD OF MANUFACTURING THEREOF

(71) Applicant: SAMSUNG ELECTRONICS CO., LTD., SUWON-SI (KR)

(72) Inventor: JUNGHO PARK, Suwon-si (KR)

(21) Appl. No.: 18/498,574

(22) Filed: Oct. 31, 2023

(30) Foreign Application Priority Data
Feb. 22, 2023 (KR) 10-2023-0023670

(51) Int. Cl. H01L 27/146

(52) U.S. Cl. CPC H01L 27/1463; H01L 27/14689

(57) ABSTRACT

The present disclosure relates to an image sensor and a method of manufacturing thereof, and the image sensor may include: a substrate including a first surface and a second surface opposite the first surface with a thickness therebetween, a plurality of unit pixels including a photoelectric conversion layer within the substrate, a pixel isolation pattern that extends from the second surface of the substrate to the first surface of the substrate within the substrate between the plurality of unit pixels, and a surface insulating film that has flat upper and lower surfaces and is disposed on the plurality of unit pixels of the substrate and the pixel isolation pattern, wherein the pixel isolation pattern includes a first pixel isolation filling film including a first material, a first void, a second pixel isolation filling film including a second material, and a second void, the second pixel isolation filling film extends from the second surface to the first surface, the second void is between the second pixel isolation filling film and the first surface, and the first material and the second material are different from each other.

### CROSS-REFERENCE TO RELATED APPLICATION

This application claims priority to and the benefit of Korean Patent Application No. 10-2023-0023670 filed in the Korean Intellectual Property Office on Feb. 22, 2023, the entire contents of which are incorporated herein by reference.

### BACKGROUND

### Field

The present disclosure relates to an image sensor, and more particularly, to an image sensor and a method for manufacturing the same.

### Description of the Related Art

An image sensor is a device that converts an optical image to an electrical signal. where, the image sensor may be classified, for example, as a charge coupled device (CCD) image sensor or a CMOS image sensor (CIS) implemented in a complementary metal oxide semiconductor (CMOS) process.

The CIS may read image information by converting light energy to electrical energy. Specifically, the CIS may convert an analog image signal generated by light introduced through a lens to an electrical image signal, where unlike the CCD image sensor that transmits a charge, the CIS may be a device developed to transmit a CMOS digital signal voltage.

The CIS may include a plurality of pixels disposed two-dimensionally, and may use a plurality of transistors for each pixel. A signal charge generated in a photodiode may be converted to a voltage within each pixel, which may then be output. Since the CIS may be manufactured by conventional CMOS technology, research on a CIS that is easy to manufacture is currently being actively conducted.

### SUMMARY

Embodiments of the present disclosure relate to providing an image sensor that addresses issues with a Front Deep Trench Isolation (FDTI) structure produced in manufacturing a CMOS image sensor (CIS).

Embodiments of the present disclosure also provide a method for manufacturing an image sensor addressing issues with a Front Deep Trench Isolation (FDTI) structure.

An image sensor according to an embodiment of the present disclosure may include: a substrate including a first surface and a second surface opposite the first surface with a thickness therebetween; a plurality of unit pixels including a photoelectric conversion layer within the substrate; a pixel isolation pattern disposed between the plurality of unit pixels within the substrate that extends from the second surface of the substrate to the first surface of the substrate; and a surface insulating film that has flat upper and lower surfaces and is disposed on the plurality of unit pixels of the substrate and the pixel isolation pattern. The pixel isolation pattern may include: a first pixel isolation filling film including a void; and a second pixel isolation filling film disposed within the void. In an embodiment, a thickness of the second pixel isolation filling film may be less than or equal to a thickness of the pixel isolation pattern.

In an embodiment, the second pixel isolation filling film may have a thickness of 3000 Å or more in a direction from the second surface to the first surface. In an embodiment, the second pixel isolation filling film may include an insulating material. In an embodiment, the insulating material may include at least one of a silicon oxide, an aluminum oxide, a hafnium oxide, a titanium oxide, a tantalum oxide, a silicon nitride, and a combination thereof.

In an embodiment, the image sensor may further include: a plurality of color filters that are disposed above the surface insulating film and corresponds to the plurality of unit pixels on the second surface of the substrate; and a micro lens disposed on the plurality of color filters. In an embodiment, the surface insulating film may be made of the same material with a predetermined range of thickness in a direction from the lower surface of the surface insulating film to the upper surface of the surface insulating film. In an embodiment, the thickness of the predetermined range may be 3000 Å or less.

An image sensor according to another embodiment of the present disclosure may include: a substrate including first and second surfaces facing each other; a plurality of unit pixels including a photoelectric conversion layer within the substrate; each of pixel isolation patterns that is disposed within the substrate, extends from the first surface of the substrate to the second surface of the substrate, separates the unit pixels, includes a first pixel isolation filling film including a void distributed in a direction from the second surface to the first surface, and includes a second pixel isolation filling film filled with a material that is different from that of the first pixel isolation filling film; a surface insulating film that has flat upper and lower surfaces and is disposed on the plurality of unit pixels of the substrate and the pixel isolation pattern; a plurality of color filters that are disposed above the surface insulating film and correspond to the plurality of unit pixels on the second surface of the substrate; and a micro lens disposed on the plurality of color filters.

In an embodiment, the pixel isolation pattern may have a shape of a deep trench formed by patterning the substrate, and a thickness of the second pixel isolation filling film may be less than or equal to a thickness of the pixel isolation pattern. In an embodiment, a thickness of the second pixel isolation filling film at a portion where the pixel isolation patterns extending in horizontal and vertical directions intersect may be different from a thickness of the second pixel isolation filling film at a portion where the pixel isolation patterns extending in the horizontal and vertical directions do not intersect.

In an embodiment, the second pixel isolation filling film may have a thickness of 5000 Å or more in a direction from the first surface to the second surface. In an embodiment, the second pixel isolation filling film may include an insulating material.

In an embodiment, the insulating material may include at least one of a silicon oxide, an aluminum oxide, a hafnium oxide, a titanium oxide, a tantalum oxide, a silicon nitride, and a combination thereof. In an embodiment, the first pixel isolation filling film may include a low-resistance conductive material.

A method for manufacturing the image sensor according to an embodiment of the present disclosure may include: providing a substrate that includes second and third surfaces facing each other; forming a first trench by etching the substrate from the third surface; forming a liner film within the first trench; filling a first pixel isolation filling film within the liner film; polishing the third surface to expose the first pixel isolation filling film; forming a second pixel isolation filling film by depositing a pre-second pixel isolation filling film on a first surface formed by polishing the third surface to fill a void within the first trench that is a region not filled by the first pixel isolation filling film; removing the pre-second pixel isolation filling film disposed on the first surface; cleaning the first surface to remove an impurity and a naturally formed oxide film on the first surface; and applying a surface insulating film on the cleaned first surface. In an embodiment, the removing of the pre-second pixel isolation filling film disposed on the first surface may include polishing to expose the first surface.

In an embodiment, the removing of the pre-second pixel isolation filling film disposed on the first surface may further include simultaneously polishing a portion of the first surface and the second pixel isolation filling film applied to at least a portion of the first surface. In an embodiment, the forming of the second pixel isolation filling film by applying the pre-second pixel isolation filling film on the first surface formed by polishing the third surface to fill the void within the first trench that is the region not filled by the first pixel isolation filling film may include filling the second pixel isolation filling film so that a thickness of the second pixel isolation filling film is less than or equal to a thickness of the first trench. In an embodiment, in the forming of the second pixel isolation filling film by applying the pre-second pixel isolation filling film on the first surface formed by polishing the third surface to fill the void within the first trench that is the region not filled by the first pixel isolation filling film, the second pixel isolation filling film may include an insulating material, and the insulating material may include at least one of a silicon oxide, an aluminum oxide, a hafnium oxide, a titanium oxide, a tantalum oxide, a silicon nitride, and a combination thereof.

In the image sensor according to an embodiment of the present disclosure, a void within a Front Deep Trench Isolation (FDTI) structure is filled so that a particle, a physical scratch, and a step difference of application are improved in a subsequent process within a front process. Thus, a risk of a change in product characteristics compared with an existing process is minimized.

The method for manufacturing the image sensor according to an embodiment of the present disclosure provides the image sensor having the above-described advantage.

### BRIEF DESCRIPTION OF THE DRAWINGS

FIG. 1 is a block diagram of an image sensor according to an embodiment of the present disclosure.

FIG. 2 is a circuit diagram illustrating a unit pixel region of a sensor array according to an embodiment of the present disclosure.

FIG. 3 is a view illustrating a conceptual layout of the image sensor according to an embodiment of the present disclosure.

FIG. 4 is a view illustrating a conceptual layout of the image sensor according to another embodiment of the present disclosure.

FIG. 5 is a layout diagram for describing the image sensor according to an embodiment of the present disclosure.

FIG. 6 is a cross-sectional view taken along a line A′-A of FIG. 5.

FIGS. 7A to 7D are enlarged views of a region P1 of FIG. 6.

FIG. 8 is an enlarged view of a region P2 of FIG. 6.

FIG. 9 is a plane view for explaining a pixel isolation pattern of a region AB of FIG. 5.

FIG. 10 is an enlarged view of a region P3 of FIG. 6.

FIGS. 11 to 18 illustrate a method for manufacturing the image sensor according to an embodiment of the present disclosure.

### DETAILED DESCRIPTION

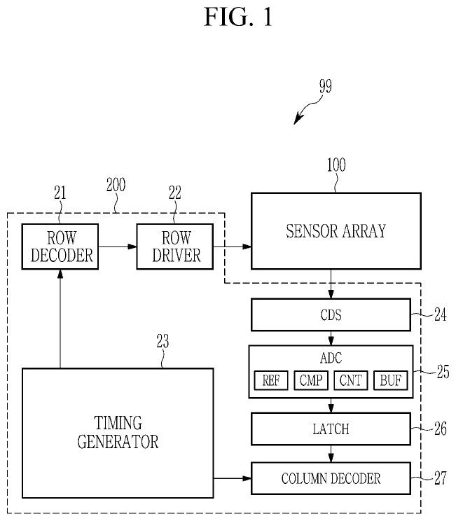

FIG. 1 is a block diagram of an image sensor according to an embodiment of the present disclosure.

Referring to FIG. 1, a semiconductor chip including a sensor array 100 and a semiconductor chip including a logic circuit 200 may be stacked to form an image sensor 99.

The sensor array 100 may convert incident light, and may generate an electrical signal. The sensor array 100 may include unit pixel regions disposed in a matrix form, as a 2-dimensional grid along row and column directions. Specifically, the sensor array 100 may be driven under control of the logic circuit 200. More specifically, the logic circuit 200 may control a plurality of transistors included in the sensor array 100.

The logic circuit 200 may efficiently receive data from the sensor array 100, and may generate an image frame. For example, the logic circuit 200 may use various methods, such as a global shutter method in which all unit pixel regions are simultaneously sensed, a flutter shutter method that adjusts an exposure time in which all unit pixel regions are simultaneously sensed, and a rolling shutter method or a coded rolling shutter method in which the unit pixel regions are controlled on a row-by-row basis.

The logic circuit 200 may include members such as a row decoder 21, a row driver 22, a timing generator 23, a correlated double sampler (CDS) 24, an analog-to-digital converter (ADC) 25, a latch device (LATCH) 26, and a column decoder 27.

The row driver 22 may control a row unit sensor array 100 disposed in units of rows according to control of the timing generator 23. The row driver 22 may select at least one row from among a plurality of rows of the sensor array 100 according to a row address. The row driver 22 may decode the row address, and may be connected to a selection transistor, a reset transistor, and a source follower transistor. The sensor array 100 may be driven by a plurality of driving signals such as a pixel selection signal, a reset signal, and a charge transmission signal received from the row driver 22.

The timing generator 23 can provide a timing signal and a control signal to the row decoder 21 and the column decoder 27. The row driver 22 can provide the plurality of driving signals for driving a plurality of unit pixels to the sensor array 100 according to a result decoded by the row decoder 21. When the plurality of unit pixels PX are disposed in a matrix form, a driving signal can be provided for each row of the matrix.

In various embodiments, the correlated double sampler (CDS) 24 receives an output signal from the sensor array 100, where the CDS can maintain and sample the received output signal. Specifically, the correlated double sampler 24 can doubly sample a specific noise level and a signal level of the output signal from pixels of the sensor array 100, and output a difference level corresponding to a difference between the noise level and the signal level, where the output can be an analog signal.

In various embodiments, the analog-to-digital converter 25 can convert an analog signal corresponding to the difference level to a digital signal to output the digital signal. Specifically, the analog-to-digital converter 25 may convert analog signals received from the sensor array 100 through column lines to digital signals. The number of analog-to-digital converters 25 may be determined according to the number of unit pixel regions disposed along one row and the number of column lines. As a non-limiting example, at least one analog-to-digital converter 25 may be provided.

The analog-to-digital converter 25 may include a reference signal generator REF, a comparator CMP, a counter CNT, and a buffer BUF. The reference signal generator REF may generate a ramp signal having a specific slope, and may provide the ramp signal as a reference signal of the comparator. The comparator CMP may compare the analog signal with the ramp signal of the reference signal generator REF, and may output comparison signals having respective transition points according to an effective signal component. The counter CNT may generate a counting signal by performing a counting operation, and may provide the counting signal to the buffer BUF. The buffer BUF includes circuits of the latch device 26 respectively connected to the column lines, and may latch the counting signal output from the counter CNT for each column in response to a transition of the comparison signal to output the latched counting signal as data.

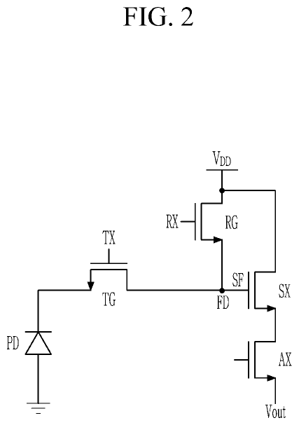

FIG. 2 is a circuit diagram illustrating the unit pixel region of the sensor array according to an embodiment of the present disclosure.

Referring to FIG. 2, the sensor array may include a photoelectric conversion layer PD (also referred to as a photo detector), a transmission transistor TX, a floating diffusion region (FD), and the reset transistor RX.

The photoelectric conversion layer PD may generate a charge in proportion to an amount of light incident from an external source. The photoelectric conversion layer PD may be a photodiode including an n-type impurity region and a p-type impurity region. The photoelectric conversion layer PD may be coupled with the transmission transistor TX that transmits generated and accumulated charges to the floating diffusion region FD. The floating diffusion region FD may be provided at one side of the transmission transistor TX. The floating diffusion region FD has a parasitic capacitance that converts the charge to a voltage, so that the charge is accumulatively stored. The floating diffusion region FD can provide conversion gain (CG).

One end of the transmission transistor TX may be electrically connected to the photoelectric conversion layer PD, and the other end of the transmission transistor TX may be electrically connected to the floating diffusion region FD, where the transmission transistor TX can provide an electrical path between the photoelectric conversion layer PD and the floating diffusion region FD that can be controlled by an applied signal. The transmission transistor TX may be formed of a transistor driven by transmission signals that are at predetermined biases. The transmission signal may be applied through a transmission gate TG. Specifically, the transmission transistor TX may transmit the charge generated from the photoelectric conversion layer to the floating diffusion region FD according to the transmission signals.

The source follower transistor SF may amplify a change in electrical potential of the floating diffusion region FD that receives the charge from the photoelectric conversion layer PD, and may output the amplified change to an output line Vout. A predetermined electrical potential (e.g., a power supply voltage VDD) provided to a drain of the source follower transistor SF may be transferred to a drain region of the selection transistor. A source follower gate SG of the source follower transistor SF may be connected to the floating diffusion region FD.

The selection transistor SX may select a unit pixel region to be read in units of rows. The selection transistor SX may be disposed at a lower portion of the source follower transistor SF. The selection transistor SX may be formed of a transistor driven by a selection line that applies a predetermined bias (e.g., a row selection signal). The row selection signal may be applied through a selection gate SEL.

The reset transistor RX may periodically reset the floating diffusion region FD. The reset transistor RX may include a transistor driven by a reset line that applies a predetermined bias (for example, a reset signal). The reset signal may be applied through a reset gate RG. When the reset transistor RX is turned on by the reset signal, a predetermined electrical potential (for example, the power supply voltage VDD) provided to a drain of the reset transistor RX may be transferred to the floating diffusion region FD.

FIG. 2 shows a form in which photoelectric conversion layers PD electrically shares one floating diffusion region FD, but this is a non-limiting example. One unit pixel region may include any one of at least one photoelectric conversion layer, the floating diffusion region FD, and the transmission, source follower, selection, and reset transistors, and the reset transistor RX, the source follower transistor SF, or the selection transistor SX may be shared by neighboring unit pixel regions.

In an embodiment, as an area of the unit pixel region decreases, the photoelectric conversion layer PD and the transmission transistor TX may be formed on one semiconductor chip, and the reset transistor RX, the source follower transistor SF, and the selection transistor SX may be formed on another semiconductor chip. The semiconductor chips may be aligned to form the unit pixel region.

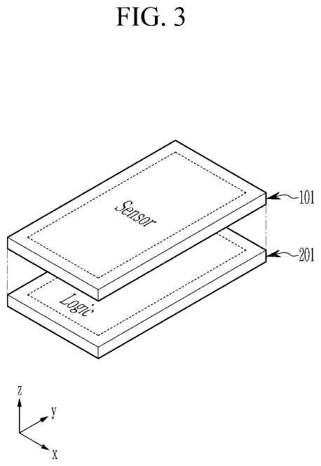

FIG. 3 is a view illustrating a conceptual layout of the image sensor according to an embodiment of the present disclosure.

Referring to FIG. 3, the image sensor 99 according to the embodiment may include a first substrate structure 101 and a second substrate structure 201 that are stacked. At the first substrate structure 101, a plurality of unit pixels may be disposed in a two-dimensional array structure in a plane including an X-axis direction and a Y-axis direction. Specifically, the first substrate structure 101 may include a sensor array 100. The X-axis direction and the Y-axis direction may be perpendicular to each other.

The second substrate structure 201 may include a structure (or a member) such as a logic region Logic. The second substrate structure 201 may be disposed below the first substrate structure 101. The first substrate structure 101 and the second substrate structure 201 may be electrically connected. The second substrate structure 201 may allow a pixel signal transferred from the first substrate structure 101 to be transferred to the logic region of the second substrate structure 201.

Logic devices of the logic circuit 200 may be disposed within a logic region of the second substrate structure 201.

The logic devices may include circuits for processing pixel signals received from the unit pixels.

The first substrate structure 101 and the second substrate structure 201 may be stacked in a Z-axis direction, where the first substrate structure 101 can be positioned on and vertically aligned with the second substrate structure 201. The Z-axis direction may be a direction perpendicular to the X-axis direction and the Y-axis direction.

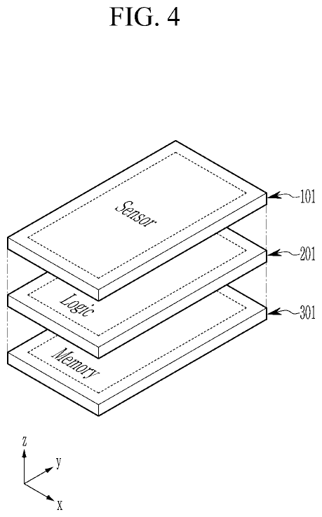

FIG. 4 is a view illustrating a conceptual layout of the image sensor according to another embodiment of the present disclosure.

Referring to FIG. 4, in an embodiment, the image sensor 99 may further include a third substrate structure 301. The first substrate structure 101, the second substrate structure 201, and the third substrate structure 301 may be sequentially stacked along the Z-axis direction. The third substrate structure 301 may be disposed below the second substrate structure 201. Specifically, the second substrate structure 201 may be disposed between the first substrate structure 101 and the third substrate structure 301. Detailed description of the first substrate structure 101 and the second substrate structure 201 is the same within a range that does not contradict the description of FIG. 3 described above.

The third substrate structure 301 may include a memory device. For example, the third substrate structure 301 may include a volatile memory device such as a DRAM or an SRAM. The third substrate structure 301 may receive a signal from the first substrate structure 101 and the second substrate structure 201 to process the signal through the memory device.

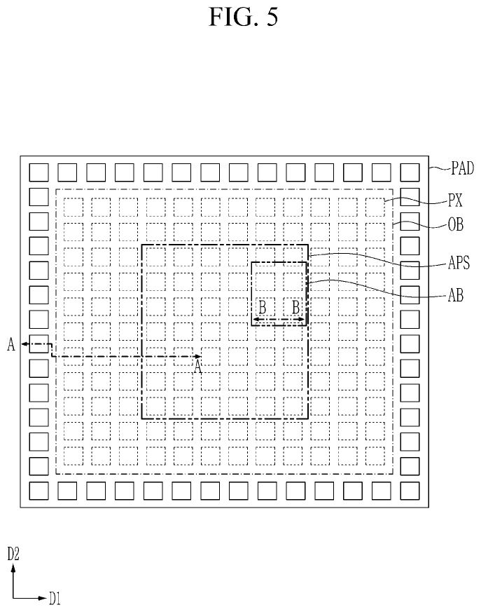

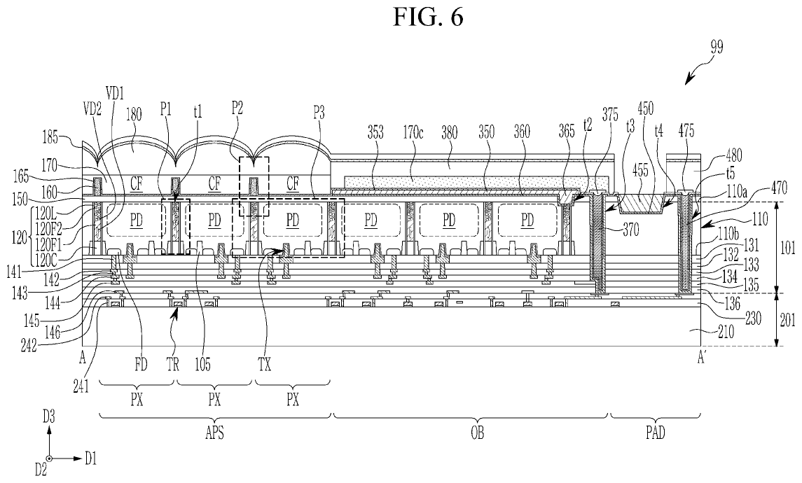

FIG. 5 is a layout diagram for describing the image sensor according to an embodiment of the present disclosure. FIG. 6 is a cross-sectional view taken along a line A′-A of FIG. 5.

Referring to FIGS. 5 and 6, the image sensor 99 according to the embodiment may include the first substrate structure 101 and the second substrate structure 201. The first substrate structure 101 and the second substrate structure 201 may be a sensor chip and a logic chip, respectively.

The first substrate structure 101 may include a light receiving region APS, a light blocking region OB, and a pad region PAD. A plurality of unit pixel regions PX disposed in a two-dimensional form (for example, a matrix form) may be formed within the light receiving region APS and the light blocking region OB. The unit pixel regions PX may be disposed in the matrix form within a plane extending in a first direction D1 and a second direction D2. The first direction D1 and the second direction D2 may cross each other. The first direction D1 and the second direction D2 may be substantially perpendicular to each other. A third direction D3 may be substantially perpendicular to the first and second directions D1 and D2.

Active pixels that receive light to generate an active signal may be disposed at the light receiving region APS. Optical black pixels that generate an optical black signal by blocking light may be disposed at the light blocking region OB. As a non-limiting example, the light blocking region OB may be formed along a periphery of the light receiving region APS.

In an embodiment, dummy unit pixel regions may be formed within the light blocking region OB. The dummy unit pixel region may be a pixel that does not generate the active signal.

The pad region PAD may be formed around the light blocking region OB, where the pad region PAD may be adjacent to an edge of the first substrate structure 101. The pad region PAD may be connected to a member, such as an external device to transmit and receive an electrical signal between the image sensor 99 and the external device. A second pad pattern 455 may be connected to the member such as the external device on a first substrate 110 of the pad region PAD.

Referring to FIG. 6, the image sensor 99 may include the first substrate 110, a pixel isolation pattern (or a pixel separation pattern) 120, a surface insulating film 150, a first color filter 170, a grid pattern 160, a micro lens 180, and a second substrate 210. In another embodiment, the image sensor 99 may include a first pad pattern 365 and the second pad pattern 455. In another embodiment, the image sensor 99 may further include a third pad pattern.

The first substrate 110 may be a semiconductor substrate. Specifically, the first substrate 110 may be a bulk silicon or a silicon-on-insulator (SOI). The first substrate 110 may be a silicon substrate. For example, the first substrate 110 may be a material including silicon, silicon germanium, indium antimonide, a lead tellurium compound, indium arsenide, indium phosphide, gallium arsenide, or gallium antimonide. In an embodiment, the first substrate 110 may have an epitaxial layer formed on a base substrate.

The first substrate 110 may include a first surface 110a and a second surface 110b opposite the first surface 110a with a thickness therebetween, where the second surface may be parallel to the first surface. In an embodiment, the first surface 110a of the first substrate 110 may be a light receiving surface on which light is incident. In an embodiment, the image sensor 99 may be a backside illuminated (BSI) image sensor.

The plurality of unit pixel regions PX may be formed within the first substrate 110 of the light receiving region APS and the light blocking region OB. Each unit pixel region PX may include the photoelectric conversion layer PD. In an embodiment, a dummy unit pixel region not including the photoelectric conversion layer PD may be further included within the first substrate 110 of the light blocking region OB, but the present disclosure is not limited thereto. A signal generated in the dummy unit pixel region may be used as information for removing a process noise in a subsequent step.

Each unit pixel region PX may include the photoelectric conversion layer PD, the floating diffusion region FD, and the transmission transistor TX. The photoelectric conversion layer PD may be formed within the first substrate 110 of the light receiving region APS and the light blocking region OB. The photoelectric conversion layer PD may generate a charge in proportion to an amount of light incident from the outside. The photoelectric conversion layer PD may transmit generated and accumulated charges to the floating diffusion region FD.

The floating diffusion region FD may be formed within the first substrate 110 of the light receiving region APS and the light blocking region OB. The floating diffusion region FD may be formed proximal to the second surface 110b of the first substrate 110. The charge transmitted to the floating diffusion region FD may be applied to the source follower gate SG of FIG. 2.

The transmission transistor TX may be buried within the first substrate 110, where the transmission transistor TX may be adjacent to the floating diffusion region FD along the second surface 110b of the first substrate 110. One end of the transmission transistor TX may be electrically connected to the photoelectric conversion layer PD, and the other end of the transmission transistor TX may be electrically connected to the floating diffusion region FD. The transmission transistor TX may transmit the charge generated from the photoelectric conversion layer PD to the floating diffusion region FD. The first wire insulating film 131 may be adjoining the second surface 110b of the first substrate 110.

The transmission transistor TX may include a transmission gate TG, a gate insulating film, and a gate spacer. The transmission gate may include a portion buried within the first substrate 110. The gate insulating film may be disposed between the transmission gate TG and the first substrate 110. The gate spacer may be disposed on both side walls of the transmission gate TG.

The pixel isolation pattern 120 may be formed within the first substrate 110. The pixel isolation pattern 120 may be formed by filling a deep trench formed by patterning the first substrate 110 with a conductive material, and a liner film that is an insulating material may be formed between the conductive material and the first substrate 110 to provide electrical insulation.

The pixel isolation pattern 120 may pass through the first substrate 110 in the third direction D3. Specifically, the pixel isolation pattern 120 may extend from the second surface 110b to the first surface 110a, where the pixel isolation pattern 120 may be a Front Deep Trench Isolation (FDTI) structure.

The pixel isolation pattern 120 may define the plurality of unit pixel regions PX. In another embodiment, the pixel isolation pattern 120 may define the plurality of unit pixel regions PX and the dummy unit pixel. The pixel isolation pattern 120 may be formed in a lattice shape on a plane to separate the plurality of unit pixel regions PX from each other.

The pixel isolation pattern 120 may have a lattice structure extending in the first and second directions D1 and D2, where the pixel isolation pattern 120 can form a grid pattern.

From a cross-sectional view, the pixel isolation pattern 120 may penetrate the first substrate 110 in the third direction D3. The pixel isolation pattern 120 may extend from the second surface 110b of the first substrate 110 to the first surface 110a. The pixel isolation pattern 120 may be a deep trench isolation (DTI) film. A width of the pixel isolation pattern 120 in the second direction D2 may gradually decrease from the second surface 110b of the first substrate 110 to the first surface 110a, such that the pixel isolation pattern 120 can have a tapered cross-section. However, the cross-sectional shape of the pixel isolation pattern 120 is not limited thereto.

The pixel isolation pattern 120 may include a liner film 120L, a first pixel isolation filling film 120F1, a second pixel isolation filling film 120F2, and a capping film 120C. The liner film 120L may be disposed along a side wall and a bottom surface of a first trench t1 formed in the first substrate 110. In an embodiment, the bottom surface of the first trench t1 can be a surface opposite the first surface 110a of the first substrate 110. The first pixel isolation filling film 120F1 and the second pixel isolation filling film 120F2 may be disposed above or on the liner film 120L, where the liner film 120L can surround the first pixel isolation filling film 120F1 and the second pixel isolation filling film 120F2. The capping film 120C may be disposed above the first pixel isolation filling film 120F1. The first pixel isolation filling film 120F1 may be proximal to the first surface 110a of the first substrate 110, and the capping film 120C may be proximal to the second pixel isolation filling film 120F2, where the second pixel isolation filling film 120F2 may be interposed between the first pixel isolation filling film 120F1 and the second pixel isolation filling film 120F2.

The liner film 120L may include an oxide film having a lower refractive index than that of the first substrate 110, where the liner film 120L and the first substrate 110 may form a wave guide. As a non-limiting example, the liner film 120L may include at least one of a silicon oxide, an aluminum oxide, a tantalum oxide, and a combination thereof.

The liner film 120L having the lower refractive index than that of the first substrate 110 may refract or reflect light obliquely incident to the photoelectric conversion layer PD, where the interface between the liner film 120L and the first substrate 110 can provide total internal reflectance with the unit pixel region PX for light impinging on the sensor array 100. The liner film 120L may prevent a photo charge generated in a specific unit pixel region PX by incident light from moving to an adjacent unit pixel region PX by random drift of the photo charge. Specifically, the liner film 120L may improve the quality of the image sensor by improving a light receiving rate of the photoelectric conversion layer PD.

The first pixel isolation filling film 120F1 may include a first material. The first pixel isolation filling film 120F1 may include an insulating material or a conductive material. The insulating material may include a silicon-based insulating material such as a silicon nitride, a silicon oxide, or a silicon oxynitride, and/or a high dielectric material, such as a hafnium oxide, an aluminum oxide, or a tantalum oxide. In an embodiment, the first pixel isolation filling film 120F1 may be a low-resistance conductive material. As a non-limiting example, the conductive material may include polysilicon (Poly Si), or silicon doped with arsenic (As), phosphorus (P), or carbon (C). In an embodiment, a negative voltage may be applied to the first pixel isolation filling film 120F1 including the conductive material. Accordingly, an electrostatic discharge (ESD) bruise defect of the image sensor may be effectively prevented. The ESD bruise defect refers to a phenomenon in which charges generated by a reaction such as the ESD are accumulated on a surface (for example, the first surface 110a) of a substrate resulting in a stain, such as bruise on an image generated by the accumulation, being generated.

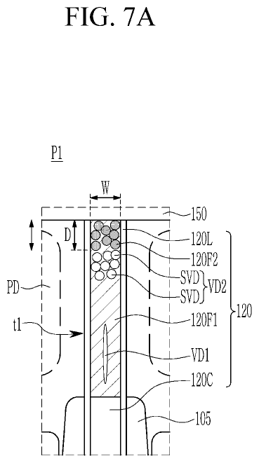

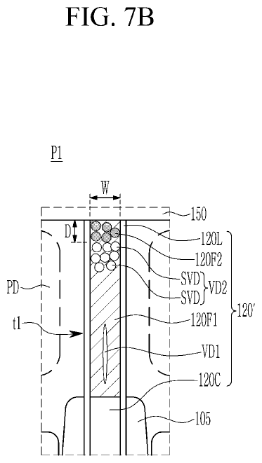

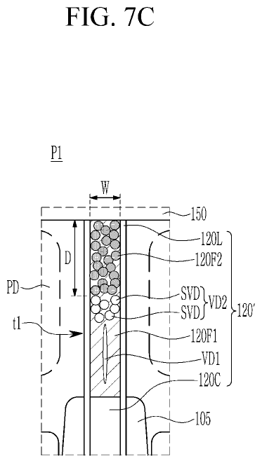

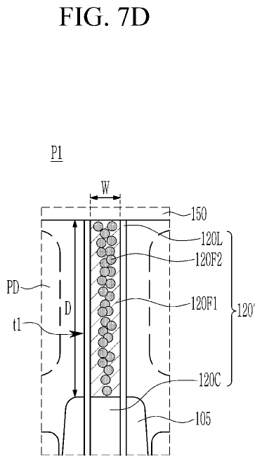

The first pixel isolation filling film 120F1 may have a void (an opening) (for example, a region not filled with the first pixel isolation filling film 120F1) distributed in a direction from the second surface 110b to the first surface 110a. Specifically, the region not filled with the first pixel isolation filling film 120F1 may include a first void V1 and a second void V2 distributed in the direction from the second surface 110b to the first surface 110a. Detailed description of the void will be described later with reference to FIGS. 7A to 7C.

The second pixel isolation filling film 120F2 may include a second material. The second pixel isolation filling film 120F2 may fill the void formed at the first pixel isolation filling film 120F1. When the first pixel isolation filling film 120F1 is made of the conductive material, the second pixel isolation filling film 120F2 may fill the void so that a portion of the first pixel isolation filling film 120F1 is separated from a periphery of the void in a process step of manufacturing the image sensor. Thus, a problem in which a voltage applied to the first pixel isolation filling film 120F1 is leaked to the photodiode may be prevented. When the first pixel isolation filling film 120F1 is made of the insulating material, the second pixel isolation filling film 120F2 may fill the void so that a portion of the first pixel isolation filling film 120F1 is separated from the periphery of the void. Thus, a problem in which transmission of light is hindered may be prevented.

In an embodiment, the second pixel isolation filling film 120F2 may include an insulating material. The insulating material may include a silicon-based insulating material such as a silicon nitride, a silicon oxide, or a silicon oxynitride, and/or a high dielectric material such as a hafnium oxide, an aluminum oxide, or a tantalum oxide. Since the second pixel isolation filling film 120F2 is made of the insulating material, the second pixel isolation filling film 120F2 may be prevented from being used as a source of leakage current so that a stable image sensor is provided.

In an embodiment, the second pixel isolation filling film 120F2 may be formed of a material that is different from that of the first pixel isolation filling film 120F1. When the first pixel isolation filling film 120F1 is made of the conductive material, the second pixel isolation filling film 120F2 may include the insulating material, so that a problem such as a short circuit does not occur between the first pixel isolation filling film 120F1 and the second pixel isolation filling film 120F2.

When the first pixel isolation filling film 120F1 is made of the insulating material, the second pixel isolation filling film 120F2 may be formed of an insulating material that is different from that of the first pixel isolation filling film 120F1. Specifically, reactivity between the insulating material of the first pixel isolation filling film 120F1 and the insulating material of the second pixel isolation filling film 120F2 may be low. As the first pixel isolation filling film 120F1 and the second pixel isolation filling film 120F2 include different materials with low reactivity, whether the second pixel isolation filling film 120F2 is filled can be checked. Thus, it is possible to provide the image sensor with high yield and high reliability in a subsequent process.

In an embodiment, a shape of the second pixel isolation filling film 120F2 may have at least one curved region. For example, the second pixel isolation filling film 120F2 may fill at least a portion of the void that the first pixel isolation filling film 120F1 does not fill, and may have an uneven shape in the first direction D1. For example, a lower region of the second pixel isolation filling film 120F2 may not be evenly filled. The second pixel isolation filling film 120F2 may be unevenly formed because the second pixel isolation filling film 120F2 is filled within the void.

The capping film 120C may include an insulating material. For example, the capping film 120C may include a silicon-based insulating material such as a silicon nitride, a silicon oxide, or a silicon oxynitride, and/or a high dielectric material such as a hafnium oxide and an aluminum oxide. As a non-limiting example, the capping film 120C may include the same material as a first capping pattern 375 and a second capping pattern 475.

In an embodiment, an element isolation pattern (also referred to as a device isolation pattern) 105 may be provided. The element isolation pattern 105 may be disposed within the first substrate 110, where the element isolation pattern 105 may extend away from the second surface 110b. For example, the element isolation pattern 105 may be disposed within a trench in which a portion of the first substrate 110 is recessed. Specifically, the trench may be recessed from the second surface 110b of the first substrate 110. The element isolation pattern 105 may be a shallow trench isolation (STI) film. The element isolation pattern 105 may define active regions.

A width of the element isolation pattern 105 in the first direction D1 or the second direction D2 may gradually decrease from the second surface 110b of the first substrate 110 towards the first surface 110a forming a tapered cross-section. The element isolation pattern 105 may overlap the pixel isolation pattern 120 in the second direction D2 or the first direction D1. The pixel isolation pattern 120 may pass through the element isolation pattern 105 in the third direction D3. The element isolation pattern 105 may include an insulating material. For example, the insulating material may include at least one of a silicon nitride, a silicon oxide, and a silicon oxynitride.

The element isolation pattern 105 may define the active regions. From a plan view, the active regions may have a line shape extending in the second direction D2, as a non-limiting example. The floating diffusion region FD, the transmission transistor TX, the selection transistor SX, the reset transistor RX, and the source follower transistor SF may be provided on the active regions. Specifically, the transmission transistor TX may include the transmission gate TG.

In an embodiment, the floating diffusion region FD may be provided at one side of the transmission transistor TX. The floating diffusion region FD may have conductivity opposite to that of the first substrate 110. For example, the floating diffusion region FD may be doped with an n-type impurity. The floating diffusion region FD may cover the transmission gate TG of the transmission transistor TX.

In an embodiment, a portion of the unit pixel region PX may include the selection transistor SX and the source follower transistor SF. The selection transistor SX may include the selection gate SEL, and the source follower transistor SF may include the source follower gate SG. Another portion of the unit pixel region PX may include the reset transistor RX. The reset transistor RX may include the reset gate RG. However, a technical idea of the present disclosure is not limited thereto, and a disposition and the number of transistors included in the unit pixel region PX may be changed.

In an embodiment, the image sensor 99 may further include first wire insulating films 131, 132, 133, 134, 135, and 136. The first wire insulating films 131, 132, 133, 134, 135, and 136 may cover the second surface 110b of the first substrate 110. The first substrate 110 and the first wire insulating films 131, 132, 133, 134, 135, and 136 may constitute the first substrate structure 101. In FIG. 6, the first wire insulating films 131, 132, 133, 134, 135, and 136 are illustrated, but the present disclosure is not limited thereto, and the number of layers of the first wire insulating films is not limited thereto, and the number of layers may be greater or less than the number of layers illustrated.

In various embodiments, the first wire insulating films 131, 132, 133, 134, 135, and 136 may include at least one of a silicon oxide, a silicon nitride, a silicon oxynitride, and a low-k material (a low dielectric constant material) having a lower dielectric constant than that of the silicon oxide, but the present disclosure is not limited thereto.

A plurality of first contacts 141 and 143 and a plurality of first wire patterns 142, 144, and 145 may be provided within the first wire insulating films 131, 132, 133, 134, 135, and 136. The plurality of first contacts 141 and 143 may electrically connect the floating diffusion region FD and the plurality of first wire patterns 142, 144, and 145. Some of the plurality of first wire patterns 142, 144, and 145 may be connected to a first connection structure 360. This is a non-limiting example, and the plurality of first contacts 141 and 143 may be connected to the plurality of first wire patterns 142, 144, and 145 in various forms, but the number of first contacts is not limited thereto.

In various embodiments, each of the plurality of first contacts 141 and 143 and the plurality of first wire patterns 142, 144, and 145 may include, for example, at least one of tungsten (W), copper (Cu), aluminum (Al), gold (Au), silver (Ag), and an alloy thereof.

The second substrate 210 may be a bulk silicon or a silicon-on-insulator (SOI). The second substrate 210 may be a silicon substrate. For example, the second substrate 210 may include silicon, silicon germanium, indium antimonide, a lead tellurium compound, indium arsenide, indium phosphide, gallium arsenide, or gallium antimonide. The second substrate 210 may have an epitaxial layer formed on a base substrate.

A plurality of transistors TR may be formed on an upper surface of the second substrate 210. The transistor TR may control the transmission transistor TX, the reset transistor RX, the selection transistor SX, and the source follower transistor SF.

A second wire insulating film 230 may be formed above the second substrate 210. For example, the second wire insulating film 230 may cover an upper surface of the second substrate 210. The second substrate 210 and the second wire insulating film 230 may constitute the second substrate structure 201. As a non-limiting example, the second wire insulating film 230 may include at least one of a silicon oxide, a silicon nitride, a silicon oxynitride, and a low-k material (a low dielectric constant material) having a lower dielectric constant than that of the silicon oxide.

A second contact 241 and a plurality of second wire patterns 242 may be disposed within the second wire insulating film 230. The second contact 241 may electrically connect the plurality of second wire patterns 242, the plurality of second wire patterns 242 may be respectively connected to the transistors TR, and may be electrically connected to the floating diffusion region FD of the first substrate structure 101. Some of the plurality of second wire patterns 242 may be electrically connected to the first connection structure 360. Further, others of the plurality of second wire patterns 242 may be electrically connected to a third connection structure 450. Others of the plurality of second wire patterns 242 shown in FIG. 6 may be electrically connected to the third connection structure 450, but this is a non-limiting example, and does not limit the present disclosure.

In various embodiments, each of the second contact 241 and the second wire patterns 242 may include, for example, at least one of tungsten (W), copper (Cu), aluminum (Al), gold (Au), silver (Ag), and an alloy thereof, but the present disclosure is not limited thereto.

The surface insulating film 150 may be formed on the first surface 110a of the first substrate 110. The surface insulating film 150 may extend along the first surface 110b of the first substrate 110. In an embodiment, at least a portion of the surface insulating film 150 may contact the pixel isolation pattern 120, where the surface insulating film 150 may be on the first pixel isolation filling film 120F1 and the liner film 120L. In this case, a lower surface of the surface insulating film 150 may evenly contact the pixel isolation pattern 120.

The surface insulating film 150 may include an insulating material. For example, the surface insulating film 150 may include at least one of a silicon oxide, a silicon nitride, a silicon oxynitride, an aluminum oxide, a hafnium oxide, a titanium oxide, a tantalum oxide, and a combination thereof, but the present disclosure is not limited thereto. In an embodiment, the surface insulating film 150 may be made of the same material as or a different material from the second pixel isolation filling film 120F2. In an embodiment, when the surface insulating film 150 is made of a material that is different from that of the second pixel isolation filling film 120F2, the material of the surface insulating film 150 and the material of the second pixel isolation filling film 120F2 may not react with each other. Since the materials of the surface insulating film 150 and the second pixel isolation filling film 120F2 are different, a problem in which a reaction between the surface insulating film 150 and the second pixel isolation filling film 120F2 is caused may be prevented.

The surface insulating film 150 may function as an antireflection film, so that reflection of light incident on the first substrate 110 is reduced or prevented and the incidence of light is facilitated. Thus, a light receiving rate of the photoelectric conversion layer PD may be improved. In addition, the surface insulating film 150 may function as a planarization film, so that the first color filter 170 and the micro lens 180 to be described below are formed with a uniform height without distortion.

The first color filter 170 may be formed above the surface insulating film 150 of the light receiving region APS. In an embodiment, the first color filter 170 may be disposed above each unit pixel region PX. Specifically, a plurality of first color filters 170 may be disposed in a two-dimensional form (for example, in a matrix form).

The first color filter 170 may have various color filters according to the unit pixel region PX. For example, the first color filter 170 may be disposed in a Bayer pattern including a red color filter, a green color filter, and a blue color filter. This is a non-limiting example, and the first color filter 170 may include a yellow filter, a magenta filter, and a cyan filter, or may further include a white filter.

The grid pattern 160 may be formed on the surface insulating film 150. The grid pattern 160 may be formed in a lattice shape on a plane to be interposed between the plurality of first color filters 170. The grid pattern 160 may improve quality of the image sensor by refracting or reflecting light obliquely incident to the image sensor. The grid pattern 160 may be aligned with the pixel isolation pattern 120.

The grid pattern 160 may include a metal material capable of reflecting light or a low refractive index material having a lower refractive index than that of silicon (Si). For example, the grid pattern 160 may include at least one of a tungsten metal, an aluminum metal, a titanium metal, a titanium nitride metal, a silicon oxide, a silicon oxide that captures (or collects) an air layer, a low refractive index polymer material, and a combination thereof, but the present disclosure is not limited thereto.

In an embodiment, a first protective film 165 may be formed on the surface insulating film 150 and the grid pattern 160. The first protective film 165 may be interposed between the surface insulating film 150 and the first color filter 170, and may be interposed between the grid pattern 160 and the first color filter 170. For example, the first protective film 165 may prevent damage to the surface insulating film 150 and the grid pattern 160.

The micro lens 180 may be formed on the first color filter 170. The micro lens 180 may be located to correspond with each unit pixel region PX. For example, micro lenses 180 may be disposed in a two-dimensional form (for example, a matrix form) on a plane.

The micro lens 180 may have a convex shape, and may have a radius of curvature within a predetermined range. Because the micro lens 180 has the radius of curvature within the predetermined range, the micro lens 180 may concentrate incident light on the photoelectric conversion layer PD. For example, the micro lens 180 may include a light-transmitting resin as a non-limiting example.

In an embodiment, a second protective film 185 may be formed on the micro lens 180. The second protective film 185 may extend along a surface of the micro lens 180. For example, the second protective film 185 may include an inorganic oxide film. As a non-limiting example, the second protective film 185 may include at least one of a silicon oxide, a titanium oxide, a zirconium oxide, a hafnium oxide, and combinations thereof. In an embodiment, the second protective film 185 may include a low temperature oxide (LTO).

The second protective film 185 may protect the micro lens 180 from the outside. For example, the second protective film 185 may protect the micro lens 180 including an organic material by including the inorganic oxide film. In addition, the second protective film 185 may improve a light condensing ability of the micro lens 180. For example, the second protective film 185 may reduce a response such as reflection, refraction, or scattering of incident light reaching the space between the micro lenses 180 by filling the space between the micro lenses 180.

In an embodiment, the image sensor 99 may further include the first connection structure 360 and the third connection structure 450. The first connection structure 360 may be formed within the light blocking region OB. The first connection structure 360 may be disposed within the light blocking region OB to block light incident to the light blocking region OB. The first connection structure 360 may be formed on the surface insulating film 150 within the light blocking region OB. The first connection structure 360 may contact the pixel isolation pattern 120.

A second trench t2 exposing the pixel isolation pattern 120 may be formed within the first substrate 110 and the surface insulating film 150 of the light blocking region OB. The first connection structure 360 may be formed within the second trench t2 to contact the pixel isolation pattern 120 within the light blocking region OB. The first connection structure 360 may extend along a profile of a side wall of the second trench t2 and a profile of a bottom surface of the second trench t2.

The first connection structure 360 may be electrically connected to the pixel isolation pattern 120. For example, the first connection structure 360 may be electrically connected to a conductive layer of the pixel isolation pattern 120. As a non-limiting example, the first connection structure 360 may include a titanium (Ti) film, a titanium nitride (TiN) film, and a tungsten (W) film that are sequentially stacked.

In an embodiment, the first pad pattern 365 may be formed on the first connection structure 360. The first pad pattern 365 may fill the second trench t2 remaining after filling the first connection structure 360. A first voltage may be applied to the pixel isolation pattern 120 through the first pad pattern 365. For example, a negative voltage may be applied to the conductive layer through the first pad pattern 365 and the first connection structure 360 that include a conductive material. Thus, the charges generated by a reaction such as the ESD may be discharged to the first pad pattern 365 through the pixel isolation pattern 120, and the ESD bruise defect may be prevented.

As a non-limiting example, the first pad pattern 365 may include at least one of tungsten (W), copper (Cu), aluminum (Al), gold (Au), silver (Ag), and an alloy thereof.

In an embodiment, a third trench t3 may be formed within the first substrate 110 of the light blocking region OB. The third trench t3 may expose some of the first wire patterns 145 and 146 of the first substrate structure 101. For example, the third trench t3 may be a through silicon via structure.

The third trench t3 may expose some of the first wire patterns 145 and 146 and the second wire pattern 242 of the second substrate structure 201. The first connection structure 360 may be formed within the third trench t3 to connect the first wire patterns 145 and 146 and the second wire pattern 242. The first connection structure 360 may extend along a side wall and a bottom surface of the third trench t3.

In an embodiment, a first filling insulating film 370 may be formed on the first connection structure 360. The first filling insulating film 370 may fill a third trench t3 remaining after filling the first connection structure 360. As a non-limiting example, the first filling insulating film 370 may include at least one of a silicon oxide, an aluminum oxide, a tantalum oxide, and a combination thereof.

In an embodiment, the first capping pattern 375 may be formed on the first filling insulating film 370. The first capping pattern 375 may include a silicon-based insulating material such as a silicon nitride, a silicon oxide, or a silicon oxynitride, and/or a high dielectric material such as a hafnium oxide and an aluminum oxide. The first capping pattern 375 may include the same material as the capping film 121C, but the present disclosure is not limited thereto.

In an embodiment, a second color filter 170C may be formed on the first connection structure 360. The second color filter 170C may be formed to cover a portion of the first protective film 165 within the light blocking region OB. The second color filter 170C may include a blue color filter as a non-limiting example.

In an embodiment, a third protective film 380 may be formed on the second color filter 170C. For example, the third protective film 380 may be formed to cover a portion of the first protective film 165 within the light blocking region OB. In an embodiment, the second protective film 185 may extend along a surface of the third protective film 380. The third protective film 380 may include a light-transmitting resin as a non-limiting example. In an embodiment, the third protective film 380 may include the same material as the micro lens 180.

The third connection structure 450 may be formed at the pad region PAD. The third connection structure 450 may be formed on the surface insulating film 150 of the pad region PAD.

In an embodiment, a fifth trench t5 exposing the second wire pattern 242 may be formed within the second substrate structure 201 of the pad region PAD. The third connection structure 450 may fill a portion of the fifth trench t5. As a non-limiting example, the third connection structure 450 may include a titanium (Ti) film, a titanium nitride (TiN) film, and a tungsten (W) film that are stacked.

In an embodiment, a third pad pattern 455 may be formed on the third connection structure 450. The third pad pattern 455 may fill a dummy trench remaining after filling the third connection structure 450. The third pad pattern may include at least one of tungsten (W), copper (Cu), aluminum (Al), gold (Au), silver (Ag), and an alloy thereof, but the present disclosure is not limited thereto.

In an embodiment, a portion of the third pad pattern 455 may be exposed. For example, an exposure opening exposing the third pad pattern 455 may be formed. Accordingly, the third pad pattern 455 may be connected to a member such as an external device to transmit/receive an electrical signal between the image sensor 99 and the external device.

A second filling insulating film 470 may be formed on the third connection structure 450. The second filling insulating film 470 may fill the fifth trench t5 remaining after filling the third connection structure 450. For example, the second filling insulating layer 470 may include at least one of a silicon oxide, an aluminum oxide, a tantalum oxide, and a combination thereof.

In an embodiment, the second capping pattern 475 may be formed on the second filling insulating film 470. The second capping pattern 475 may include a silicon-based insulating material such as a silicon nitride, a silicon oxide, or a silicon oxynitride, and/or a high dielectric material such as a hafnium oxide and an aluminum oxide. As a non-limiting example, the second capping pattern 475 may include the same material as the capping film 121C.

In an embodiment, a fourth protective film 480 may be formed on the third connection structure 450 of the pad region PAD. For example, the fourth protective film 480 may be formed to cover a portion of the first protective film 165 within the pad region PAD. In an embodiment, the second protective film 185 may extend along a surface of the fourth protective film 480. The fourth protective film 480 may include a light-transmitting resin as a non-limiting example, and the fourth protective film 480 may be made of the same material as the micro lens 180.

In an embodiment, the image sensor 99 may further include a fourth connection structure. The fourth connection structure may be further formed within the light blocking region OB. The fourth connection structure may be formed within the light blocking region OB to block incident light. The fourth connection structure may be formed above or on the surface insulating film 150 of the light blocking region OB.

The fourth connection structure may contact at least a portion of the pixel isolation pattern 120. The fourth connection structure may contact at least a portion of the conductive layer of the pixel isolation pattern 120. The fourth connection structure may refer to the third connection structure 360 within a non-contradictory range.

In an embodiment, a sixth trench exposing the pixel isolation pattern 120 may be formed within the first substrate 110 and the surface insulating film 150 of the light blocking region OB. The fourth connection structure may be formed within the sixth trench to contact at least a portion of the pixel isolation pattern 120 within the light blocking region OB. The fourth connection structure may extend along a profile of a side wall of the sixth trench and a profile of a bottom surface of the sixth trench.

The fourth connection structure may be electrically connected to the pixel isolation pattern 120. Specifically, as a non-limiting example, the fourth connection structure may include a titanium (Ti) film, a titanium nitride (TiN) film, and a tungsten (W) film that are sequentially stacked.

In an embodiment, a fourth pad pattern may be formed above or on the fourth connection structure. The fourth pad pattern may fill the sixth trench remaining after filling the fourth connection structure. A voltage may be applied to the pixel isolation pattern 120 through the fourth pad pattern and the fourth connection structure that include a conductive material. For example, the voltage may be a well bias voltage.

As a non-limiting example, the fourth pad pattern may include at least one of tungsten (W), copper (Cu), aluminum (Al), gold (Au), silver (Ag), and an alloy thereof.

FIGS. 7A to 7D are enlarged views of a region P1 of FIG. 6.

Referring to FIG. 7A, in an embodiment, the pixel isolation pattern 120 may include the first pixel isolation filling film 120F1, the second pixel isolation filling film 120F2, a first void VD1, and a second void VD2. The first void VD1 and the second void VD2 refer to hollow regions generated by not completely filling the pixel separation pattern 120 when the first pixel isolation filling film 120F1 is filled. The first void VD1 may be disposed below the second void VD2, and specifically, may be disposed between the second void VD2 and the second surface 110b.

In an embodiment, a shape of the first void VD1 may extend from the first surface 110a to the second surface 110b. In another embodiment, the shape of the first void VD1 may extend from the second surface 110b to the first surface 110a. As a non-limiting example, the first void VD1 may have a shape extending in the direction D3 of FIG. 6.

In an embodiment, the second void VD2 may include a plurality of sub-voids SVD. For example, the second void VD2 may include the plurality of sub-voids SVD having a plurality of island shapes. A shape of the sub-void SVD is shown as a circular shape in FIG. 7A, but this may be a non-limiting example, and the sub-void SVD may have a regular or irregular shape, and may have a circular shape, a quadrangular shape, a polygonal shape, or a mixture thereof.

In an embodiment, the pixel isolation pattern 120 may have a deep trench shape formed by patterning the first substrate 110, and the second pixel isolation filling film 120F2 may be filled in a direction from the first surface 110a to the second surface 110b. A thickness of the second pixel isolation filling film 120F2 with respect to a width W of the first trench t1 may be less than or equal to a thickness of the first trench t1. Specifically, the thickness of the second pixel isolation filling film 120F2 may mean a length of the first trench t1 from the first surface 110a of the substrate 110 to the second surface 110b, and the second pixel isolation filling film 120F2 may fill a void formed when the first pixel isolation filling film 120F1 fails to fill less than or equal to the thickness of the first trench t1.

Referring to FIG. 7B, in an embodiment, the second pixel isolation filling film 120F2 may be filled in a direction from the first surface 110a to the second surface 110b, and a ratio of a thickness D of a region filled with the second pixel isolation filling film 120F2 to the width W of the first trench t1 may be less than 1. Even if the second pixel isolation filling film 120F2 is filled in the above-described ratio, a silicon by-product may not remain outside the DTI film and the image sensor without distortion or defect may be provided.

Referring to FIG. 7C, in an embodiment, the second pixel isolation filling film 120F2 may be filled in a direction from the first surface 110a to the second surface 110b, and the ratio of the thickness D of the region filled with the second pixel isolation filling film 120F2 to the width W of the first trench t1 may be greater than or equal to 1. Specifically, a value obtained by dividing the width W of the first trench t1 by the thickness D of the region filled with the second pixel isolation filling film 120F2 may be equal to or greater than 1.

More specifically, the second pixel isolation filling film 120F2 may fill a void (VD) remaining in a thickness range thicker than the width W of the first trench t1. In an embodiment, the second pixel isolation filling film may be filled with a thickness of 3000 Å or more in a direction from the first surface 110a to the second surface 110b. For example, the thickness may be 4000 Å or more, or the thickness may be 5000 Å thick or more. The second pixel isolation filling film 120F2 may fill the void (VD) remaining in the thickness range thicker than the width W of the first trench t1 so that the silicon by-product does not remain outside the DTI film, and the surface insulating film 150 may be evenly applied to the first surface 110a so that the image sensor without distortion or defect is provided.

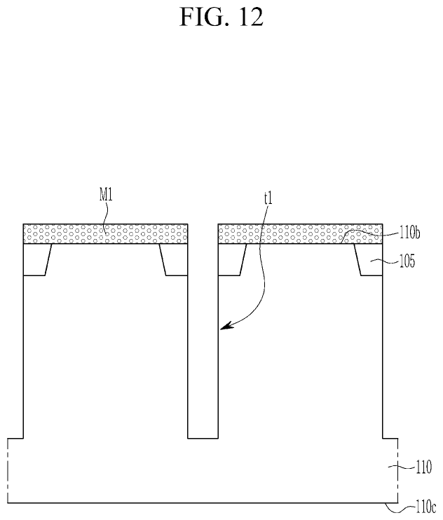

In an embodiment, a region filled with the second pixel isolation filling film 120F2 within the pixel isolation pattern 120 may be filled by less than or equal to a half of a total thickness of the first trench t1. The second pixel isolation filling film 120F2 has to fill the void VD of FIG. 12 remaining in the thickness range thicker than the width W of the first trench t1, and it is shown that an upper limit value may be a half of the total thickness of the first trench t1.

Referring to FIG. 7D, in an embodiment, it is shown that the region filled with the second pixel isolation filling film 120F2 within the pixel isolation pattern 120 may fill the void remaining within the total thickness of the first trench t1. By filling the void VD remaining within the total thickness of the first trench t1, all the void VD remaining within the first pixel isolation filling film 120F1 may be removed to prevent a step difference due to the void VD.

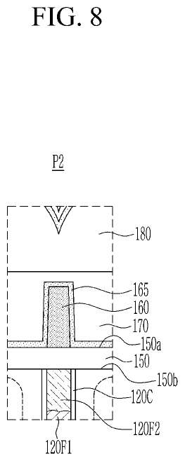

FIG. 8 is an enlarged view of a region P2 of FIG. 6 for explaining the surface insulating film 150 according to an embodiment of the present disclosure.

Referring to FIG. 8, the surface insulating film 150 may include flat upper and lower surfaces, and the image sensor may include a plurality of color filters 170 corresponding to the plurality of unit pixels PX above or on the first surface 110a of the substrate 110 and the micro lens 180 disposed on the plurality of color filters 170. Specifically, since the second pixel isolation filling film 120F2 fills at least a portion of the void VD remaining within the first pixel isolation filling film 120F1 and the surface insulating film 150 is disposed on the first surface 110a after going through a polishing and cleaning process, the surface insulating film 150 may include the flat upper and lower surfaces. Cleaning the first surface can remove an impurity and a naturally formed oxide film on the first surface. For example, a void (VD) between a surface adjacent to the first surface 110a of the surface insulating film 150 and the first surface 110a may be filled by the second pixel isolation filling film 120F2, so that it is possible to improve a problem of a scratch on a surface of a silicon (Si) substrate around the void (VD).

In an embodiment, the surface insulating film 150 may be made of the same material with a predetermined range of thickness in a direction from a lower surface of the surface insulating film 150 to an upper surface of the surface insulating film 150. For example, the same material with a predetermined range of thickness in a direction from a lower surface of the surface insulating film 150 to an upper surface of the surface insulating film 150, may include the same insulating material. Specifically, the second pixel isolation filling film 120F2 may fill the void (VD) within the pixel isolation pattern 120 that the first pixel isolation filling film 120F1 does not fill and a portion where the scratch occurs on the surface of the silicon (Si) substrate around the void (VD), and then CMP may be performed on the surface insulating film 150 disposed on the pixel isolation pattern 120. Thus, there is an advantage of improving the scratch phenomenon.

In an embodiment, the thickness of the predetermined range may be 3000 Å or less. The same insulating material may include an impurity (for example, a material such as a silicon by-product).

The surface insulating film 150 includes flat upper and lower surfaces. Thus, when members such as the plurality of color filters 170 and the micro lens 180 are stacked on the surface insulating film 150, it is possible to prevent a problem of hindering a light receiving power and reducing reliability of a product.

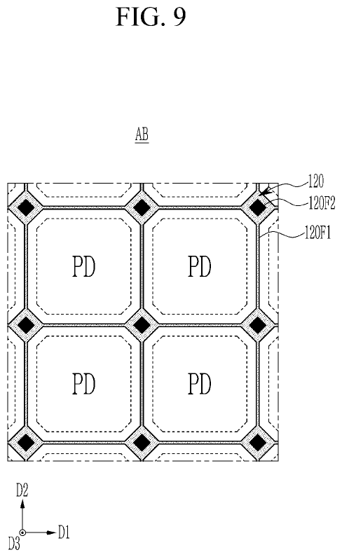

FIG. 9 is a plane view for explaining the pixel isolation pattern 120 of a region AB of FIG. 5.

Referring to FIG. 9, in an embodiment, a void (VD) may exist at a portion where pixel isolation patterns 120 extending in horizontal and vertical directions intersect and a portion (for example, within a straight line pattern) where the pixel isolation patterns 120 extending in the horizontal and vertical directions do not intersect, and the second pixel isolation filling film 120F2 may be filled in the void (VD).

In an embodiment, a thickness of the second pixel isolation filling film 120F2 at a portion where the pixel isolation patterns 120 extending in the horizontal and vertical directions intersect may be different from a thickness of the second pixel isolation filling film 120F2 at a portion where the pixel isolation patterns 120 extending in the horizontal and vertical directions do not intersect. The horizontal direction may be a D1 direction, the vertical direction may be a D2 direction, and a portion (for example, a middle region of the region AB of FIG. 9) where the pixel isolation patterns 120 extending in the horizontal and vertical directions intersect may have a plurality of voids VD compared with a portion (for example, a region disposed at an edge of a central portion of the region AB of FIG. 9) where the pixel isolation patterns 120 extending in the horizontal and vertical directions do not intersect.

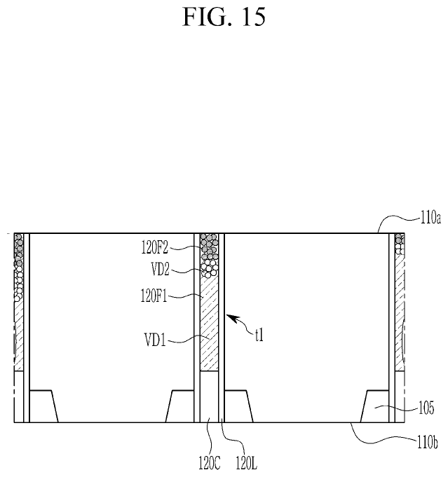

The second pixel isolation filling film 120F2 may be applied to the first surface 110a in the same amount as that of a pre-second pixel isolation filling film 120F2P of FIG. 15A described later, so that a thickness of the second pixel isolation filling film 120F2 at a portion where the pixel isolation patterns 120 extending in the horizontal and vertical directions intersect may be different from a thickness of the second pixel isolation filling film 120F2 at a portion where the pixel isolation patterns 120 extending in the horizontal and vertical directions do not intersect. Even if the thickness of the second pixel isolation filling film 120F2 at the portion where the pixel isolation patterns 120 extending in the horizontal and vertical directions intersect is different from the thickness of the second pixel isolation filling film 120F2 at the portion where the pixel isolation patterns 120 extending in the horizontal and vertical directions do not intersect, a defective problem such as a white spot characteristic or a black defect in an image sensor product may be improved.

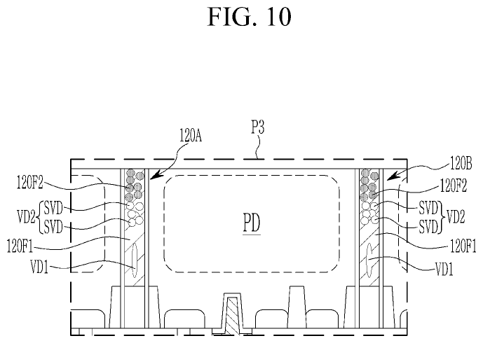

FIG. 10 is an enlarged view of a region P3 of FIG. 6.

Referring to FIG. 10, in an embodiment, the image sensor may include a first pixel isolation pattern 120A and a second pixel isolation pattern 120B. In an embodiment, the first pixel isolation pattern 120A may include a first pixel isolation filling film 120F1, a second pixel isolation filling film 120F2, a first void VD1, and a second void VD2, and the second pixel isolation pattern 120B may include a third pixel isolation filling film 120F3, a fourth pixel isolation filling film 120F4, a third void VD3, and a fourth void VD4. Detailed description of the first pixel isolation pattern 120A may be referred to the above-described description.

The third pixel isolation filling film 120F3 may include a first material. The fourth pixel isolation filling film 120F4 may include a second material. The first material and the second material are the same within a range that does not contradict those described in the first pixel isolation filling film 120F1 and the second pixel isolation filling film 120F2. In an embodiment, a shape of the second pixel isolation filling film 120F2 may be different from that of the fourth pixel isolation filling film 120F4. Shapes of voids that are not filled by the first pixel isolation filling film 120F1 and the third pixel isolation filling film 120F3 may be different for each pixel isolation pattern. As shapes of voids within the pixel isolation patterns are different, shapes of the second pixel isolation filling film 120F2 and the fourth pixel isolation filling film 120F4 may be different.

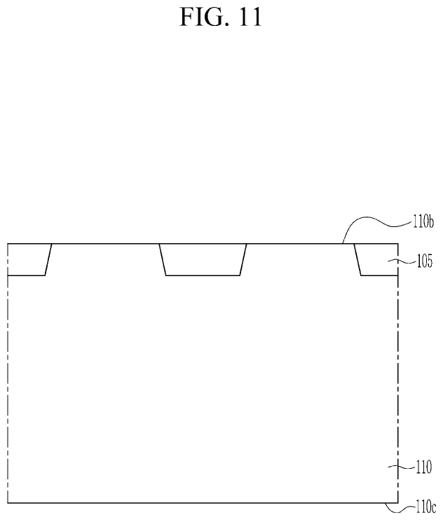

FIGS. 11 to 18 illustrate a method for manufacturing the image sensor according to an embodiment of the present disclosure. Referring to FIG. 11, the first substrate 110 including the second surface 110b and a third surface 110c facing each other may be provided, where the third surface 110c can be opposite the second surface 110b with a thickness therebetween.

The element isolation pattern 105 may be formed within the first substrate 110. First, a trench in which a portion of the second surface 110b of the first substrate 110 is recessed may be formed within the first substrate 110. The element isolation pattern 105 may be formed within the trench. The element isolation pattern 105 may define the active regions.

Referring to FIG. 12, a first mask film M1 may be formed on the second surface 110b of the first substrate 110. The first mask film M1 may have an opening that roughly limits a position of the first trench t1. The first mask film M1 may be formed of at least one of a photoresist film, an amorphous carbon layer (ACL), a spin on hardmask (SOH), a spin-on carbon (SOC) film, a silicon oxide film, and a silicon nitride film. Thereafter, the first trench t1 may be formed using the first mask film M1 as an etching mask. The first trench t1 may pass through the element isolation pattern 105.

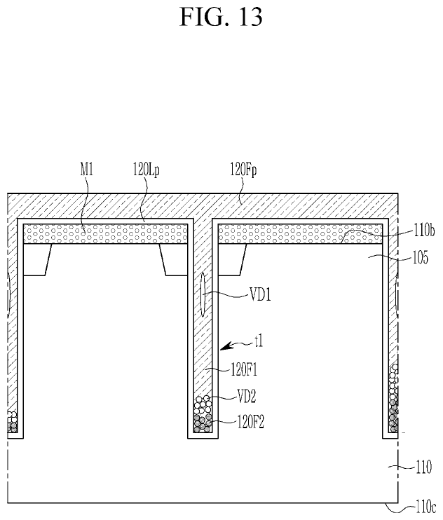

Referring to FIG. 13, a pre-liner film 120Lp may be formed along a side wall and a bottom surface of the first trench t1. A pre-first pixel isolation filling film 120Fp may be formed on the pre-liner film 121Lp.

The pre-liner film 121Lp may extend along an upper surface of the first mask film M1. The pre-liner film 121Lp may include an insulating material. As a non-limiting example, the pre-liner film 121Lp may include at least one of a silicon oxide, an aluminum oxide, a tantalum oxide, and a combination thereof.

The pre-first pixel isolation filling film 120Fp may include an insulating material or a conductive material. The insulating material may include a silicon-based insulating material such as a silicon nitride, a silicon oxide, or a silicon oxynitride, and/or a high dielectric material such as a hafnium oxide, an aluminum oxide, or a tantalum oxide. For example, the conductive material may include polysilicon (Poly Si), or silicon doped with arsenic (As), phosphorus (P), boron (B), or carbon (C), but the present disclosure is not limited thereto.

The pre-first pixel isolation filling film 120Fp may be formed deep in a direction from the second surface 110b to the third surface 110c to form a Front Deep Trench Isolation (FDTI) structure, and in this case, a portion (for example, a void VD) in which the pre-first pixel isolation filling film 120Fp is not filled within the first trench t1 may be formed. The void VD may be formed at the bottom of first trench t1, where the void VD can be adjacent to the pre-liner film 120Lp at the bottom of the first trench t1. Specifically, the void VD may include the first void VD1 and the second void VD2. Detailed description of the first void VD1 and the second void VD2 may be referred to the above-described description.

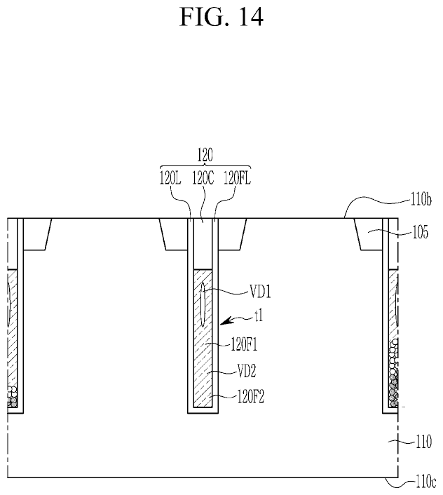

Referring to FIG. 14, the pixel isolation pattern 120 may be formed. The pixel isolation pattern 120 may include the liner film 120L, the first pixel isolation filling film 120F1, and the capping film 121C. First, a portion of the first pixel isolation filling film 120Fp may be etched to form the first pixel isolation filling film 120F1. The first pixel isolation filling film 120F1 may be formed through an etch-back process. Thereafter, a pre-capping film may be formed above or on the first pixel isolation filling film 120F1. Thereafter, a portion of the pre-capping film, a portion of the pre-liner film 121Lp, and the first mask film M1 may be removed to form the liner film 120L and the capping film 120C. The portion of the pre-capping film, the portion of the pre-liner film 121Lp, and the first mask film M1 may be removed to expose the second surface 110b of the first substrate 110.

Referring to FIG. 15, the first surface 110a may be formed by polishing the third surface 110c that is a rear surface of the first substrate 110. To polish the third surface 110c, various polishing methods such as chemical mechanical polishing (CMP) may be used as a non-limiting example. Through the polishing method, polishing may be performed so that a portion of the first pixel isolation filling film 120F1 or a portion of a region where the void VD is formed is exposed on the same line as the first surface 110a.

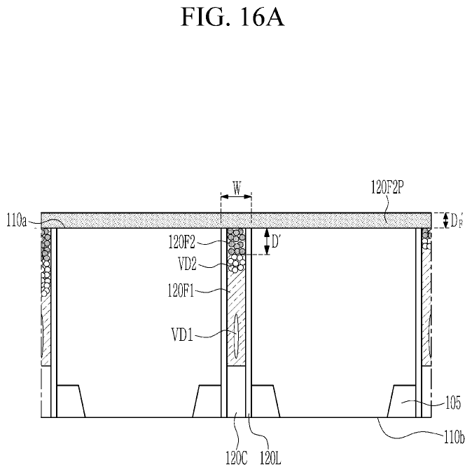

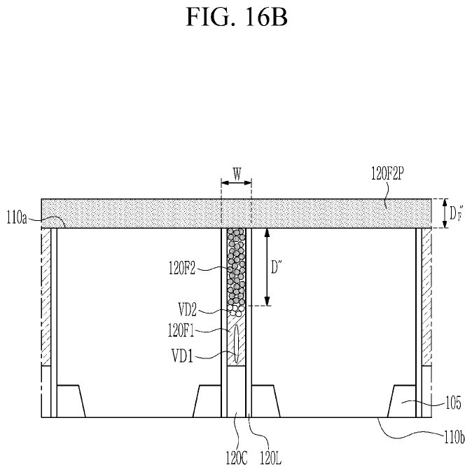

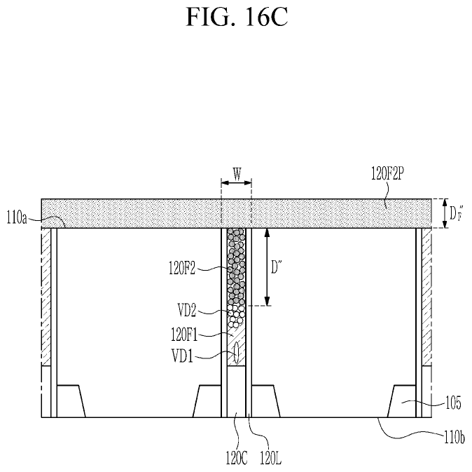

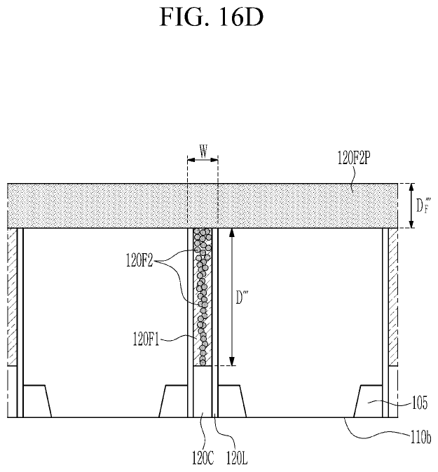

Referring to FIG. 16A, the pre-second pixel isolation filling film 120F2P may be applied on the first surface 110a to form the pre-second pixel isolation filling film 120F2P at the region where the void is formed. The second pixel isolation filling film may include an insulating material. The insulating material may include a silicon-based insulating material such as a silicon nitride, a silicon oxide, or a silicon oxynitride, and/or a high dielectric material such as a hafnium oxide, an aluminum oxide, a tantalum oxide, or a titanium oxide.

In a step of applying a pre-filling material FT on the first surface 110a, an application thickness D_{F} of the pre-filling material FT may be controlled according to the thickness D for filling the void VD within the first pixel isolation filling film 120F1. In FIG. 16A, it is possible to fill a void disposed in a thickness range of one or more times the width W of the first trench t1.

Referring to FIG. 16B, in an embodiment, the pre-filling material FT may fill a void disposed less than one time the width W of the first trench t1 to form the second pixel isolation filling film 120F2. Even if the pre-filling material FT fills the void disposed less than one time the width W of the first trench t1, it is possible to improve a problem of a scratch on a surface adjacent to an upper periphery of the first trench t1.

Referring to FIG. 16C, the pre-filling material FT may fill a void disposed one or more times the width W of the first trench t1 to form the second pixel isolation filling film 120F2. Specifically, the pre-filling material FT may fill a void disposed less than or equal to a half D″ of a total thickness of the first pixel isolation filling film 120F1 to form the second pixel isolation filling film 120F2.

Referring to FIG. 16D, the pre-second pixel isolation filling film 120F2P may fill a void disposed one or more times the width W of the first trench t1 to form the second pixel isolation filling film 120F2. Specifically, the pre-second pixel isolation filling film 120F2P may fill a void disposed within a total thickness D_{F}′″ of the first pixel isolation filling film 120F1 to form the second pixel isolation filling film 120F2. Referring back to FIGS. 16A to 16D, the void formed in the first pixel isolation filling film 120F1 may be filled with the second pixel isolation filling film 120F2 so that a step difference of the void within the deep trench isolation (DTI) film is improved and insufficient dispersion of the first pixel isolation filling film 120F1 is compensated for in a front process. As shown in FIG. 16D, the second pixel isolation filling film 120F2 may completely fill the first void VD1 and the second void VD2.

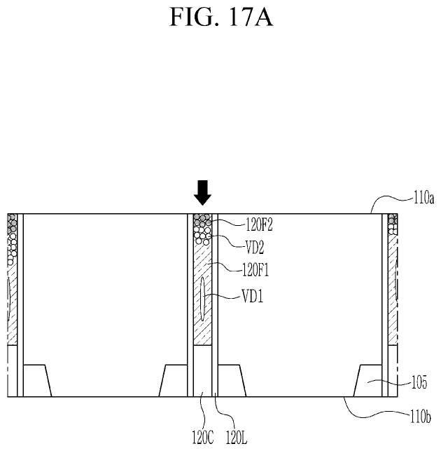

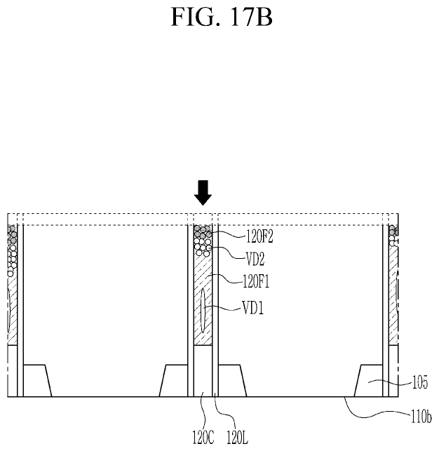

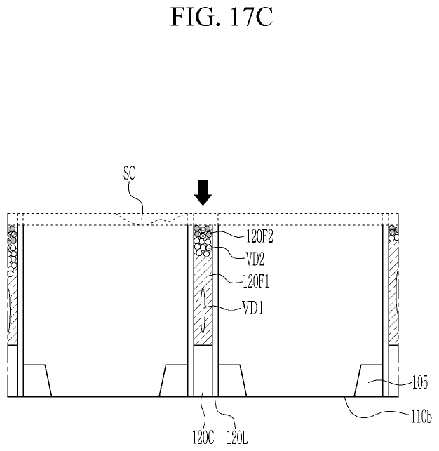

Referring to FIG. 17A, the pre-second pixel isolation filling film 120F2P applied on the first surface 110a may be removed. The pre-second pixel isolation filling film 120F2P may be applied on the first surface 110a so that the second pixel isolation filling film 120F2 is formed by filling the void formed in the first pixel isolation filling film 120F1 and a member (for example, an application layer remaining on the first surface 110a) remaining after forming the second pixel isolation filling film 120F2 is formed.

Thereafter, the remaining application layer may be removed through a polishing process. In order to polish the remaining application layer, various polishing methods such as chemical mechanical polishing (CMP) may be used as a non-limiting example.

Referring to FIG. 17B, in an embodiment, a step of removing the pre-second pixel isolation filling film 120F2P applied on the first surface 110a may include a step of polishing the pre-second pixel isolation filling film 120F2P applied on at least a portion of the first surface 110a and a portion of the first surface 110a. Specifically, in order to perform a more elaborate planarization operation in the removing of the pre-second pixel isolation filling film 120F2P applied on the first surface 110a, a portion of the first surface 110a may be exposed by including a step of further polishing a portion of the first surface 110a of the silicon substrate. Removal of the pre-second pixel isolation filling film disposed on the first surface can further include simultaneously polishing a portion of the first surface and the second pixel isolation filling film applied to at least a portion of the first surface. An additional polishing process for removing a portion of the first surface 110a of the silicon substrate may be performed. The portion of the first surface 110a of the silicon substrate may be removed together with the applied pre-second pixel isolation filling film 120F2P so that planarization is performed by adjusting a final thickness of the substrate 110 and at the same time the applied pre-second pixel isolation filling film 120F2P is removed.

Referring to FIG. 17C, the step of removing the pre-second pixel isolation filling film 120F2P applied on the first surface 110a may simultaneously polish a scratch region SC. A scratch may occur on a portion of the first surface 110a while the third surface 110c is being polished. The scratch may cause a defect or distortion in a manufacturing process of the image sensor. Therefore, a step of polishing the scratch region SC together with the pre-second pixel isolation filling film 120F2P applied on the first surface 110a may be performed.

Thereafter, a step of cleaning the first surface 110a of the substrate 110 may be performed. As a non-limiting example, the step of cleaning of the first surface 110a of the substrate 110 may be a step of cleaning the first surface using a material such as HF. A case in which the second pixel isolation filling film 120F2 fills the void formed in the first pixel isolation filling film 120F1 and the above-described polishing step is performed as in the present disclosure, may prevent a problem in which an impurity such as Si dust generated by the void in a conventional cleaning step remains on the first surface 110a, a problem of a scratch on the first surface 110a around the void in a conventional polishing process such as CMP, and the like.

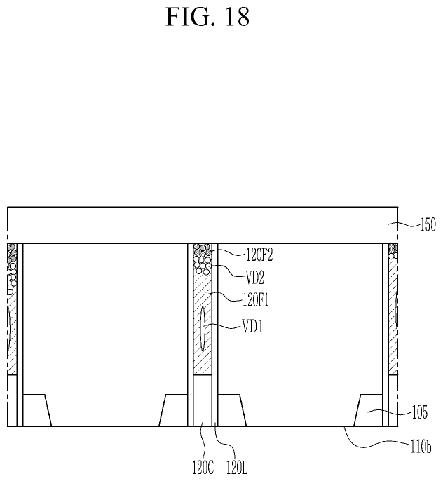

Referring to FIG. 18, the surface insulating film 150 may be applied on the cleaned first surface 110a. The surface insulating film 150 may include an insulating material. For example, the surface insulating film 150 may include at least one of a silicon oxide, a silicon nitride, a silicon oxynitride, an aluminum oxide, a hafnium oxide, a tantalum oxide, a titanium oxide, and a combination thereof, but the present disclosure is not limited thereto.

In the pixel isolation pattern 120, at least a portion of the remaining void VD that is not filled by the first pixel isolation filling film 120F1 may be filled with the second pixel isolation filling film 120F2, so that the pixel isolation pattern 120 includes a pixel isolation pattern in which the first void VD1 and the second void VD2 are formed.

The second pixel isolation filling film 120F2 may fill the void formed in the first pixel isolation filling film 120F1 and the above-described polishing step may be performed so that the surface insulating film 150 is applied in a state in which the impurity such as Si dust and the scratch do not remain on the first surface 110a. Thus, the surface insulating film 150 may be evenly applied. As the surface insulating film 150 is evenly applied, members such as the color filter 170 and the micro lens 180 deposited in a subsequent process may be formed to have a uniform height in order to prevent distortion.

The present disclosure is not limited to the embodiments, but may be manufactured in a variety of different forms, and those of ordinary skill in the art to which the present disclosure pertains will understand that the present disclosure may be implemented in other specific forms without changing the technical spirit or an essential feature of the present disclosure. Therefore, it should be understood that the above-mentioned embodiments are just examples in all aspects and are not limited thereto.

### DESCRIPTION OF SYMBOLS

110: first substrate
PD: photoelectric conversion layer
PX: unit pixel region
120: pixel isolation pattern
120F1: first pixel isolation filling film
120F2: second pixel isolation filling film
150: surface insulating film
180: micro lens

What is claimed is:

1. An image sensor comprising:
a substrate including a first surface and a second surface opposite the first surface with a thickness therebetween;
a plurality of unit pixels including a photoelectric conversion layer within the substrate;
a pixel isolation pattern that extends from the second surface of the substrate to the first surface of the substrate within the substrate between the plurality of unit pixels; and
a surface insulating film that has flat upper and lower surfaces and is disposed on the plurality of unit pixels of the substrate and the pixel isolation pattern,
wherein the pixel isolation pattern includes a first pixel isolation filling film including a first material, a first void, a second pixel isolation filling film including a second material, and a second void, the second pixel isolation filling film extends from the second surface to the first surface, the second void is between the second pixel isolation filling film and the first surface, and the first material and the second material are different from each other.

2. The image sensor of claim 1, wherein a shape of the second pixel isolation filling film has at least one curved portion.

3. The image sensor of claim 1, wherein the first material includes polysilicon, and the second material includes one of an oxide and a metal material.

4. The image sensor of claim 3, wherein the metal material includes at least one of tungsten and aluminum.

5. The image sensor of claim 1, wherein a shape of the first void extends from the first surface to the second surface or from the second surface to the first surface.

6. The image sensor of claim 1, wherein the second void includes a plurality of sub-voids, and the sub-voids have different shapes.

7. The image sensor of claim 1, wherein the surface insulating film is made of the same material with a predetermined range of thickness in a direction from the lower surface of the surface insulating film to the upper surface of the surface insulating film.

8. The image sensor of claim 7, wherein the thickness of the predetermined range is 3000 Å or less.

9. An image sensor comprising:
a substrate including a first surface and a second surface opposite the first surface with a thickness therebetween;
a plurality of unit pixels including a photoelectric conversion layer within the substrate;
a first pixel isolation pattern including a first pixel isolation filling film including a first material, a first void, a second pixel isolation filling film including a second material, and a second void; and
a second pixel isolation pattern including a third pixel isolation filling film including a first material, a third void, a fourth pixel isolation filling film including a second material, and a fourth void,
wherein the second pixel isolation filling film and the fourth pixel isolation filling film extend from the second surface to the first surface, the second void is between the second pixel isolation filling film and the first surface, the fourth void is between the fourth pixel isolation filling film and the first surface, the first material is different from the second material, and a shape of the second pixel isolation filling film is different from a shape of the fourth pixel isolation filling film.

10. The image sensor of claim 9, wherein the pixel isolation pattern has a shape of a deep trench formed by patterning the substrate, and a thickness of each of the second pixel isolation filling film and the fourth pixel isolation filling film is less than or equal to a thickness of the deep trench.

11. The image sensor of claim 10, wherein a thickness of each of the second pixel isolation filling film and the fourth pixel isolation filling film at a portion where the pixel isolation patterns extending in horizontal and vertical directions intersect is different from a thickness of the second pixel isolation filling film at a portion where the pixel isolation patterns extending in the horizontal and vertical directions do not intersect.

12. The image sensor of claim 9, wherein each of the second pixel isolation filling film and the fourth pixel isolation filling film has a thickness of 5000 Å or more in a direction from the first surface to the second surface.

13. The image sensor of claim 9, wherein the second pixel isolation filling film includes an insulating material.

14. The image sensor of claim 13, wherein the insulating material includes at least one of a silicon oxide, an aluminum oxide, a hafnium oxide, a titanium oxide, a tantalum oxide, a silicon nitride, and a combination thereof.

15. The image sensor of claim 10, wherein a region of the second pixel isolation filling film is different from a region of the fourth pixel isolation filling film.

16. A method for manufacturing an image sensor, comprising:
providing a semiconductor substrate that includes a second surface and a third surface opposite the second surface with a thickness therebetween;
forming a first trench by etching the substrate from the third surface;
forming a liner film within the first trench;
filling a first pixel isolation filling film within the liner film;
polishing the third surface to expose the first pixel isolation filling film and form a first surface;
forming a second pixel isolation filling film by depositing a pre-second pixel isolation filling film to fill a void within the first trench;
removing the pre-second pixel isolation filling film disposed on the first surface;
cleaning the first surface to remove an impurity and a naturally formed oxide film on the first surface; and
applying a surface insulating film on the cleaned first surface.

17. The method of claim 16, wherein the removing of the pre-second pixel isolation filling film disposed on the first surface includes polishing to expose the first surface.

18. The method of claim 17, wherein the removing of the pre-second pixel isolation filling film disposed on the first surface further includes simultaneously polishing a portion of the first surface and the second pixel isolation filling film applied to at least a portion of the first surface.

19. The method of claim 16, wherein the forming of the second pixel isolation filling film by applying the pre-second pixel isolation filling film on the first surface formed by polishing the third surface to fill the void within the first trench that is the region not filled by the first pixel isolation filling film, includes filling the second pixel isolation filling film so that a thickness of the second pixel isolation filling film is less than or equal to a thickness of the first trench.

20. The method of claim 16, wherein in the forming of the second pixel isolation filling film by applying the pre-second pixel isolation filling film on the first surface formed by polishing the third surface to fill the void within the first trench that is the region not filled by the first pixel isolation filling film, the second pixel isolation filling film includes an insulating material, and the insulating material includes at least one of a silicon oxide, an aluminum oxide, a hafnium oxide, a titanium oxide, a tantalum oxide, a silicon nitride, and a combination thereof.
